(19) United States
(12) Patent Application Publication
(10) Pub. No.: US 2011/0299089 A1
(43) Pub. Date: Dec. 8, 2011

(54) COMPACT LIQUID CRYSTAL BASED FOURIER TRANSFORM SPECTROMETER SYSTEM

(75) Inventors: Wei-Chih Wang, Sammamish, WA (US); Chu-Yu Huang, Seattle, WA (US)

(73) Assignee: UNIVERSITY OF WASHINGTON, Seattle, WA (US)

(21) Appl. No.: 13/154,304

(22) Filed: Jun. 6, 2011

Related U.S. Application Data
(60) Provisional application No. 61/351,700, filed on Jun. 4, 2010.
(60) Provisional application No. 61/408,776, filed on Nov. 1, 2010.
(60) Provisional application No. 61/493,885, filed on Jun. 6, 2011.

(51) Int. Cl. G01J 3/45; H05K 13/00

(52) U.S. Cl. 356/451; 29/592.1; 349/1

(57) ABSTRACT

Systems and methods for a compact Fourier transform spectrometer. A cell having two transparent walls and containing a liquid crystal medium is placed in a light beam. Applying a voltage across the cell causes the liquid crystal molecules to orient at a certain angle, wherein the angle is a function of the voltage applied. The refractive index if the cell is dependent upon the orientation of the liquid crystal molecules, and from the refractive index of the cell an optical path difference between ordinary and extraordinary waves can be calculated. Accordingly, any suitable optical path difference can be achieved by varying the voltage across the cell for a Fourier transform analysis.

### CROSS-REFERENCE TO RELATED APPLICATIONS

This application claims priority to pending U.S. Provisional Application No. 61/351,700, filed Jun. 4, 2010, pending U.S. Provisional Application No. 61/408,776, filed Nov. 1, 2010, and to pending U.S. Provisional Application No. 61/493,885, filed Jun. 6, 2011, all of which are incorporated herein by reference in their entireties.

### TECHNICAL FIELD

The present technology is directed generally to a liquid crystal cell for a Fourier transform spectrometer system and associated systems and methods.

### BACKGROUND

Spectroscopy is a fundamental analytical tool utilized in many chemical and biological analysis applications, including environmental sensing, botanical, and ecological analysis, and clinical and biochemical studies. There are many approaches to spectroscopy. Fourier transform spectroscopy (“FTS”) is well-known and widely used for its powerful analytical technique to measure the spectra of a weakly extended source. Unlike other methods, FTS analyzes all wavelengths simultaneously, a feature called the Multiplex Advantage or Fellgett Advantage. This feature makes FTS faster at spectrum analysis than grating or Fabry-Perot-based spectrometers. Further, FTS can yield a much higher throughput than with a dispersive spectrometer. Another advantage of FTS spectroscopy is a higher signal-to-noise ratio.

There are currently many commercially available FTS mechanisms, primarily in fields that require high resolution. FIG. 1, for example, illustrates a conventional Fourier transform spectrometer 5 based on a Michelson interferometer. The spectrometer 5 includes a light source 10 that emits a light beam 11. The light beam 11 is split into two beams by a beam splitter 12. A first beam 13 is directed to a first mirror 14, and the second beam 15 is directed to a second mirror 16. The second mirror 16 can be movable toward and away from the beam splitter 12 to change the path distance of the second beam 15. The spectrometer 5 has a natural reference point when the moving and fixed mirrors are the same distance from the beam splitter 12. This condition is called zero path difference. The first and second beams 13, 15 reflect from the mirrors 14, 16 back through the beam splitter 12 and onto a detector 18. When the beams recombine, the detector 18 measures an optical path difference between the first and second beams 13, 15. The second mirror 16 is movable toward and away from the detector 18 along arrow D to alter the optical path difference. A Fourier transform can be performed to analyze the light and achieve spectroscopy results in a manner that is known in the art. Spectrometers like that shown in FIG. 1, including a moving mirror 16, are relatively complex, require moving parts, and can be error-prone. Accordingly, conventional spectrometers like the one depicted in FIG. 1 are generally not suitable for portable applications and use “in the field.” The moving mirror requires a high-precision control mechanism, necessitating a large size, high weight, and high cost. The size and mass of conventional spectrometers makes them ill-suited for on-site analysis and/or analysis in challenging environments (e.g., measurement of oxygen levels in the sap of trees, on-site blood analysis, etc.).

### BRIEF DESCRIPTION OF THE DRAWINGS

FIG. 1 illustrates a conventional Fourier transform spectrometer according to the prior art.

FIG. 2 is a partially schematic illustration of a Fourier transform spectrometer assembly including a cell configured in accordance with embodiments of the present technology.

FIG. 3 illustrates a single liquid crystal molecule within the cell of FIG. 2 and an incident light beam according to the present technology.

FIG. 4 illustrates a single liquid crystal molecule under an electric field according to embodiments of the present technology.

FIG. 5A depicts a cell for a Fourier transform spectrometer configured in accordance with embodiments of the present technology.

FIG. 5B depicts the cell of FIG. 5A under an electrical field.

FIG. 6 is a partially schematic illustration of a Fourier transform spectrometer assembly including a cell configured in accordance with embodiments of the present technology.

FIG. 7A is an exploded view of a cell for a Fourier transform spectrometer configured in accordance with embodiments of the present technology.

FIG. 7B is a partially assembled view of the cell of FIG. 7A.

FIG. 8 illustrates a conditioning operation for an orientation layer for a cell of a Fourier transform spectrometer configured in accordance with embodiments of the present technology.

FIGS. 9A-9D are partially schematic, isometric views illustrating a manufacturing process for forming a cell of a Fourier transform spectrometer according to embodiments of the present technology.

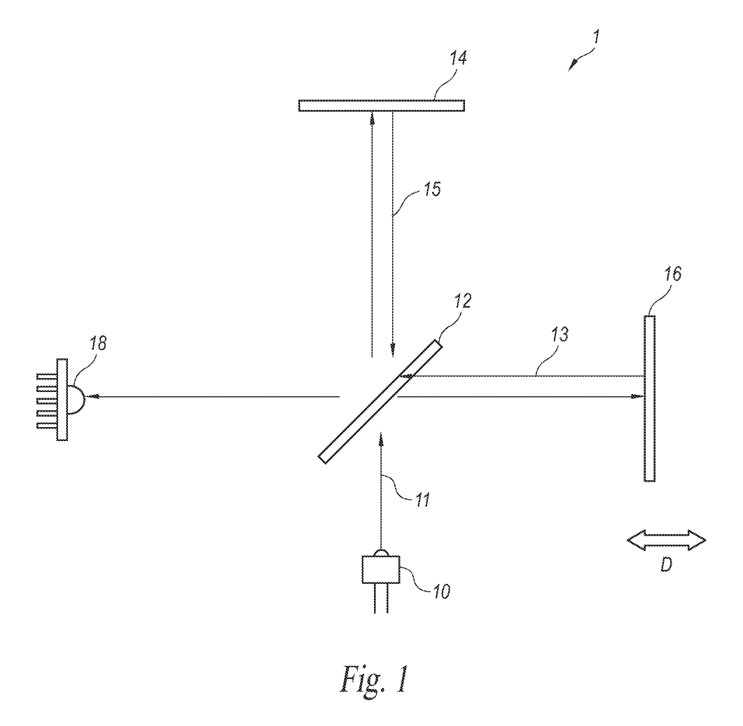

### DETAILED DESCRIPTION

The present technology is directed to a Fourier transform spectrometer assembly including a cell for altering the optical path distance of a beam of light. In some embodiments, the cell includes a pair of transparent walls on opposite sides of the cell and a liquid crystal fluid within the cell. The liquid crystal fluid has a refractive index that depends, at least in part, upon an orientation of molecules of the liquid crystal fluid. The orientation of the molecules of the liquid crystal fluid depends, at least in part, upon an electric field within the cell. The assembly also includes a source of electric energy configured to create a variable electric field within the cell, a light source configured to direct a beam of light through the cell, and a detector configured to receive the beam of light after passing through the cell and measure the optical path difference between the beam of light and a reference.

The present technology is also directed to a Fourier transform spectrometer for measuring a refracted beam of light. In some embodiments, the spectrometer includes a light source, a detector configured to receive the beam of light from the light source and measure characteristics of the beam of light, and a cell positioned between the light source and the detector. The cell can contain a substance having an index of refraction that is dependent upon an electric field across the cell. The spectrometer can also include a power source configured to apply the electric field across the cell in a controllable, variable manner.

The present technology is further directed to a method of manufacturing a cell for a Fourier transform spectrometer. In some embodiments, the method includes forming a pair of cell walls by depositing an electrode layer on a glass substrate, and fabricating an orientation layer on the electrode layer. The method can also include placing a spacer between the cell walls with the orientation layer contacting the spacer and facing inward, placing a liquid crystal material between the cell walls and the spacer, and forming an epoxy material between the cell walls and around at least a portion of the spacer to seal the liquid crystal material within the cell. The method can further include connecting a power source to the electrode layer on each of the cell walls, wherein the power source is configured to apply a variable electric field across the cell. The method can also include forming a first opening in the cell and a second opening in the cell, the second opening being opposite the first opening, and raising the isotropic temperature of the liquid crystal material. The method can further include depositing a quantity of the liquid crystal material on the first opening to permit capillary action to draw the quantity of liquid crystal material through the opening and into the cell, cooling the cell, and sealing the first opening and the second opening.

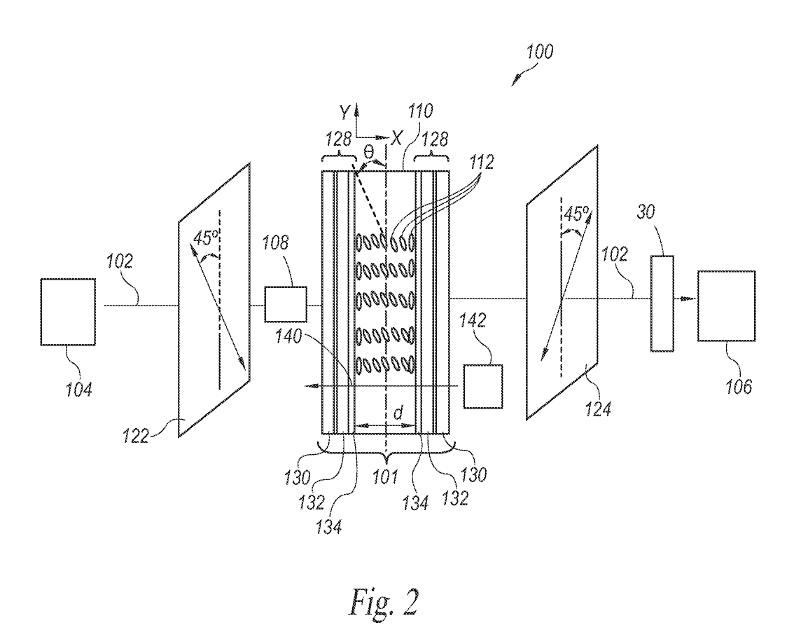

Specific details of several embodiments of the technology are described below with reference to FIGS. 2-9D. Other details describing well-known structures and systems often associated with Fourier transform spectrometer analysis systems have not been set forth in the following disclosure to avoid unnecessarily obscuring the description of the various embodiments of the technology. Many of the details, dimensions, angles, and other features shown in the Figures are merely illustrative of particular embodiments of the technology. Accordingly, other embodiments can have other details, dimensions, angles, and features without departing from the spirit or scope of the present technology. A person of ordinary skill in the art, therefore, will accordingly understand that the technology may have other embodiments with additional elements, or the technology may have other embodiments without several of the features shown and described below with reference to FIGS. 2-9D.

FIG. 2 is a partially schematic illustration of an assembly 100 for a Fourier transform spectrometer including a cell 101 according to embodiments of the present technology. The cell 101 can include a liquid crystal fluid 110 comprising liquid crystal molecules 112 suspended within the fluid 110 and held within the cell 101. The cell 101 can be positioned between a light source 104 and a light detector 106. In some embodiments, the light source 104 includes one or more broadband light sources such as quartz tungsten halogen, laser arrays, light-emitting diodes, or other suitable light sources. The light source 104 can be positioned to emit a light beam 102 through the cell 101 and onto the detector 106. The light source 102 can include a reduction lens and/or a collimating lens (not shown). A quartz wave plate 108 can be positioned in the path of the light beam 102 to add phase shift or phase retardation to improve the reading of a zero path difference of the light beam 102. The detector can be a broadband light detector such as a visible spectrum (silicon-based) detector, a near-infrared (NIR) (GeAs-based) detector, an IR (Ge or Cd-based) detector, or a broadband thermopile detector. Other suitable detectors can also be used. The cell 101 can include transparent walls 128 on either side of the cell 101. In some embodiments, the walls 128 include a glass substrate 130, an electrode layer 132, and an orientation layer 134. In some embodiments, the walls 128 are identical on either side of the cell 101. In other embodiments, however, the walls 128 may have different arrangements. The cell 101 can be enclosed around a perimeter of the cell 101 to maintain the liquid crystal fluid 110 within the cell 101 in a manner that is described more fully below. The assembly 100 can also include light filters at various positions relative to the cell 101, such as a first polarizer 122 (between the light source 104 and the cell 101) and a second polarizer 124, or analyzer (between the cell 101 and the light detector 106).

The spectrometer assembly 100 can operate as follows. After the light beam 102 passes through the cell 101 and is altered as described in greater detail below, the light beam 102 passes through a sample 30. Due to the absorption of the materials in the sample 30, some light is absorbed by the sample 30 and some passes through the sample 30. The transmitted light is then routed to a Fourier transform interferometer where signals are modulated and form a multi-wavelength time domain interferogram. The optical signal is then converted to electrical signal by the detector 106 and sends the electrical signal to a data acquisition system (not shown) for analysis by software such as LabVIEW™ or other suitable software. The signal can then be transformed from time domain to frequency domain for further analysis.

An oscillating behavior of transmitted intensity (squares of the amplitudes) can be observed by the detector 106 in dependence on the optical path difference between the ordinary and extraordinary waves. The equation below shows the relationship between transmitted intensity and the phase difference between the ordinary and extraordinary components of the propagating light.

$$I = {I}_{O} {sin}^{2} ( \frac{Δ φ}{2} )$$

Δφ is the phase difference between the ordinary and extraordinary wave. The optical path difference can be controlled by changing the magnitude of the applied voltage. In some embodiments, the cell 101 includes a voltage source 142 electrically connected to the cell 101 and to the walls of the cell 101. The voltage source can be electrically connected to the electrode layer 132 on either side of the cell 101 and configured to apply a voltage 140, or electric field, across the liquid crystal fluid 110. The voltage 140 can cause the liquid crystal molecules 112 to orient themselves as shown by the angle θ as a function of the voltage supplied. The refractive index of extraordinary axis nₑ(x) across the cell 101 is non-constant because not all molecules 112 will orient to exactly the same angle θ, therefore

$$Δ φ = \frac{2 π}{λ} {\int }_{0}^{d} [ {n}_{e} ( x ) - {n}_{o} ] d x = \frac{2 π d}{λ} ( {n}_{eff} - {n}_{o} )$$

Where the effective refractive index of the extraordinary axis, n_{eff}, is given by

$${n}_{eff} = \frac{1}{d} {\int }_{0}^{d} [ {n}_{e} ( x ) ] d x$$

The optical path difference can be calculated from the effective refractive index, n_{eff}. The optical path difference between the ordinary and extraordinary components of the light beam 102 can be controlled by changing the magnitude of the applied voltage 140 from the voltage source 142. Therefore, by varying the voltage from the voltage source 142 across the cell 101, the optical path difference in the light beam 102 can be detected by the detector 106 without needing any moving parts. In some embodiments, this effectively simulates the optical path difference achieved by conventional Fourier transform spectrometers, but without moving parts. Further, in many situations, having a greater optical path difference is advantageous because it gives greater resolution in the spectroscopy analysis.

In general, liquid crystal fluids are substances that exhibit a phase of matter that has properties between those of a conventional liquid and those of a solid crystal. There are many different types of liquid crystal phases, including the nematic phase (as shown in FIG. 2), where molecules flow with center of mass positions randomly distributed as in a liquid, but all pointing in generally the same direction. In some embodiments, the liquid crystal fluid 110 can be any material that changes index of refraction in response to an electric field. For example, the cell 101 can include an electro-optic polymer, cadmium tendulum, neo polymers, polymer-based liquid crystals, polymer dispersed liquid crystals, or any other suitable material. Many nematic liquid crystals are uniaxial, having one axis that is longer and two other axes that are generally equivalent. These types of liquid crystal molecules 112 can be approximated as cylinders or rods.

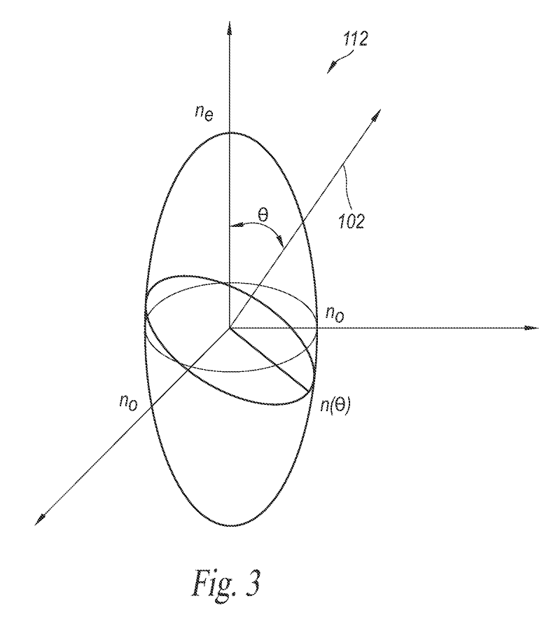

FIG. 3, for example, illustrates a single liquid crystal molecule 112, an incident beam of light 102, and a refractive index. The molecule 112 has a birefringence that can be represented by assigning two different refractive indices to the material for different polarizations:

Δn=nₑ−nₒ

where nₒ and nₑ are the refractive indices for polarizations perpendicular (ordinary) and parallel (extraordinary) to the axis of anisotropy, respectively. The refractive index n(θ) of the molecule 112 can be modulated by changing the angle θ between the optic axis and the incident beam 102. With the first polarizer 122 and the second polarizer 124 positioned at 45° with respect to the incident beam 102, polarized light propagating along the cell 101 experiences a phase difference between the ordinary and extraordinary components of the light beam 102. The cell 101 can be used within a spectrometer that can perform a Fourier transform on the light to achieve the desired spectroscopy results.

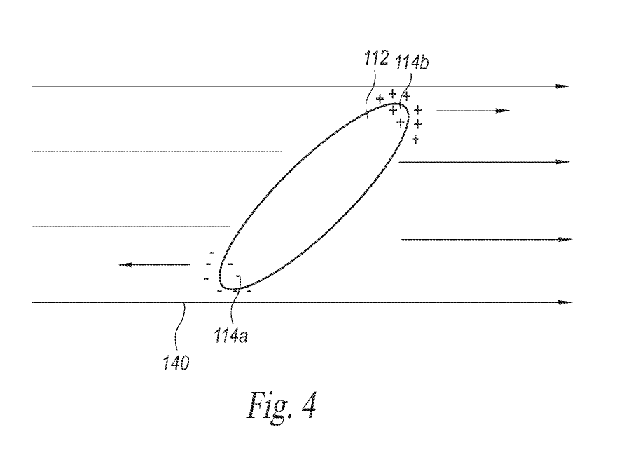

FIG. 4 illustrates a single liquid crystal molecule 112 under an external electric field 140. The molecule 112 is polar; one end 114a of the molecule 112 has a net negative charge while the other end 114b has a net positive charge. When the external electric field 140 is applied to the liquid crystal fluid 110, the molecule 112 tends to orient along the direction of the field 140 (as shown by the arrows).

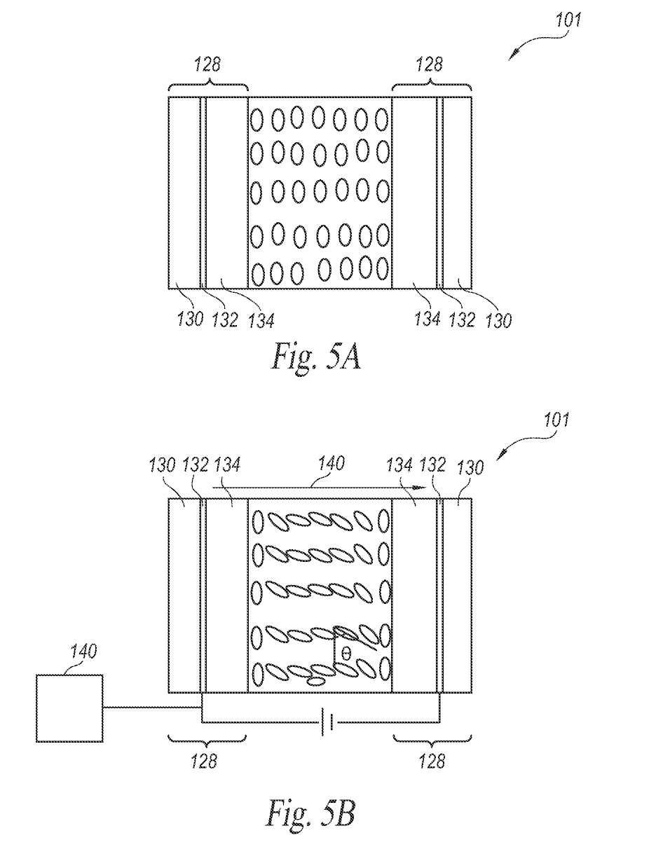

FIG. 5A illustrates the cell 101 in a neutral position, and FIG. 5B illustrates the cell 101 with an applied voltage 140 according to embodiments of the present technology. As best seen in FIG. 5A, when in the neutral (or non-energized) state, the molecules 112 are generally vertically aligned. In FIG. 5B, the liquid crystal fluid 110 is under an applied voltage 140 between the walls 128 of the cell 101. In this situation, the molecules 112 tend to orient themselves away from vertical and with the polar ends directed toward the walls 128. The voltage required to achieve the desired orientation of the liquid crystal molecules 112 is a function of the size of the cell 101. In some embodiments, for example, the walls of the cell 101 can be spaced apart by approximately 125 μm. In other embodiments, however, the cell 101 can have different dimensions.

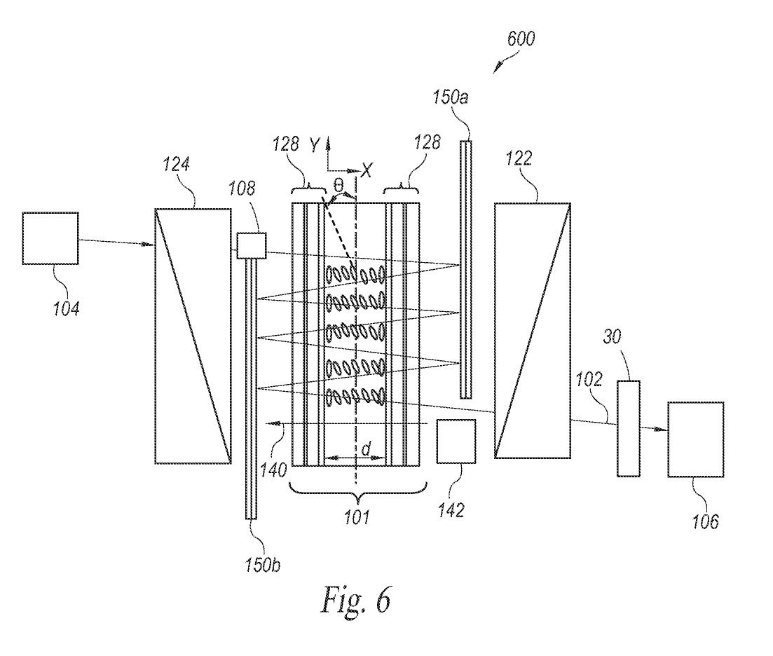

FIG. 6 is a partially schematic illustration of an assembly 600 configured in accordance with another embodiment of the present technology. The assembly 600 includes a number of features generally similar to the features of the assembly 100 described above with reference to FIG. 2. In this embodiment, however, the assembly 600 further includes a first mirror 150a positioned on a first side of the cell 101, and a second mirror 150b positioned on a second side of the cell 101 opposite the first side. In some embodiments, the first and second mirrors 150a and 150b may be offset and the light beam 102 can be angled as shown, with the light beam 102 passing just beyond an edge of the second mirror 150b, striking the first mirror 150a, and reflecting back and forth between the first mirror 150a and the second mirror 150b before ultimately passing beyond the first mirror 150a and toward the detector 106.

As mentioned previously, the optical path difference is a function of the length of the path of the light beam 102 through the cell 101. By positioning the first and second mirrors 150a and 150b on either side of the cell 101, the optical path can be multiplied by the number of passes through the cell 101 that the light beam 102 must take. This orientation can be arranged to pass the light beam 102 through the cell 101 any suitable number of times. In the embodiment shown in FIG. 6, for example, the light 102 passes through the cell 101 seven times resulting in a seven-fold increase in the optical path difference achieved. In other embodiments, a different arrangement can result in a different number of passes through the cell 101. As stated above, the required voltage for achieving a certain orientation of the molecules 112 is generally related to the size of the cell 101. Accordingly, by reflecting the light 102 through the cell 101 multiple times, it is possible to achieve a desired optical path difference with a smaller cell 101 and requiring less applied voltage 140.

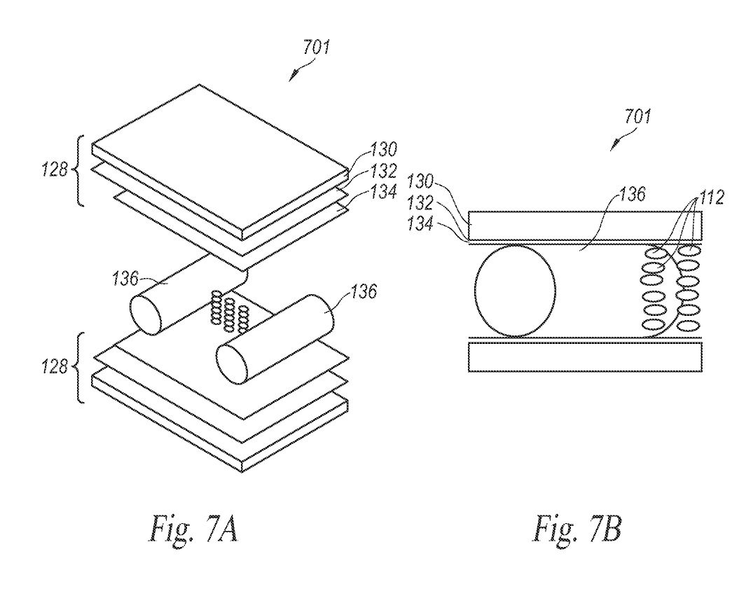

FIG. 7A is an exploded view of a cell 701 configured in accordance with yet another embodiment of the present technology, and FIG. 7B is a cross-sectional, unexploded view of the cell 701 of FIG. 7A. The cell 701 includes a number of features generally similar to the features of the cell 701 described above with reference to FIG. 2. For example, as described above, the walls 128 can comprise a glass substrate 130, an electrode layer 132, and an orientation layer 134. Further, in some embodiments, the walls 128 may be identical. In other embodiments, however, the walls 128 can be different. In the embodiment illustrated in FIGS. 7A and 7B, the cell 701 can include a spacer 136 positioned between the walls 128 to create an interior space within the cell 701 to hold the liquid crystal fluid 110 within the cell 701. The spacers 136 can be any suitable structure to withstand and maintain the liquid crystal fluid 110 within the cell 701. In some embodiments, the spacer 136 is a section of an optical fiber. The dimensions of the spacers 136 define the thickness of the cell 701. As discussed above, the optical path difference is a function of the size of the cell 701. Accordingly, the spacer 136 can be chosen according to the desired size and pass distance of the cell 701.

The electrode layer 132 is generally transparent and electrically conductive. The transparency of the electrode layer 132 permits the light beam 102 to pass through the walls 128 without significantly losing intensity. The electrode layer 132 can be deposited on the glass substrate 130 using a variety of methods. In some embodiments, for example, the electrode layer 132 can be deposited using electron beam evaporation, physical vapor deposition, or other sputter deposition techniques. The electrode layer 132 can be composed of indium tin oxide, which is a mixture of indium (III) oxide In₂O₃ and tin (IV) oxide SnO₂. In some embodiments, the electrode layer 132 can be ninety percent In₂O₃ and ten percent SnO₂ by weight. The material can be transparent and colorless and relatively thin. In other embodiments, however, the electrode layer 132 may be composed of other suitable materials. In some embodiments, the electrode layer 132 is approximately 100 nm thick and has a sheet resistance of between 70 and 100 ohms. In other embodiments, however, the electrode layer 132 may have a different thickness.

The orientation layer 134 can be included to maintain the liquid crystal molecules 112 oriented uniformly even when the cell 101 is in a non-energized state. The orientation layer 134 can be chosen to have good thermal stability, chemical resistance, and mechanical strength. In some embodiments, for example, the orientation layer 134 is a polyimide layer of imide monomers. In other embodiments, the orientation layer 134 can be a polyimide compounded with graphite or glass fiber reinforcements and can have a flexural strength of up to 50,000 psi. The film thickness of the orientation layer can be approximately 1 μm. In other embodiments, however, the orientation layer 134 may have a different configuration and/or be composed of different materials.

The orientation layer 134 can be deposited on the electrode layer 132 to form the walls 128 using any of a variety of suitable methods. In other embodiments, for example, the orientation layer 134 can be spin-coated. In one particular example, a spinner can be used to spin coat a precursor solution of polyamic acid and an organic solvent such as N-Methylpyrrolidone (NMP) on the orientation layer 134. In some embodiments, the spin setting is 500 rpm for five seconds and then 3,000 rpm for approximately 30 seconds. After spin coating the orientation layer 134 can be cured at 200-300° Celsius for approximately an hour. In other embodiments, however, the orientation layer 134 may be formed on the electrode layer 132 using other suitable techniques and/or materials.

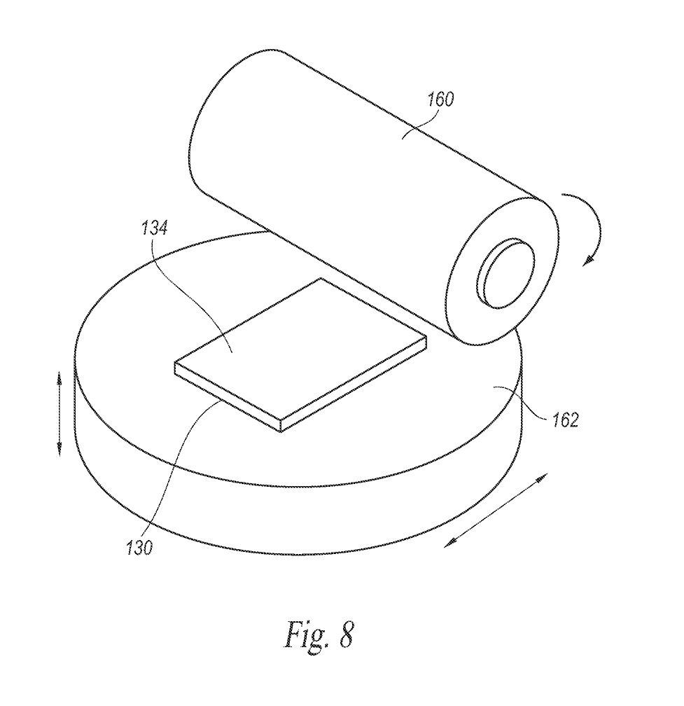

FIG. 8 illustrates an embodiment for conditioning the orientation layer 134 of the cell 101 of FIG. 2 according to some embodiments of the present technology. This process is an optional step that may not be used in some embodiments. Without wishing to be bound by any particular theory, it is believed that rubbing the orientation layer 134 helps to align the liquid crystal molecules 112 in a uniform or homogeneous direction even when the cell 101 is not energized. Accordingly, the orientation layer 134 can be rubbed in a direction relative to the eventual path of light through the cell 101 to achieve a desired orientation in a non-energized state of the cell 101. In some embodiments, for example, the orientation layer 134 can be rubbed with a velvet cloth wrapped around a rotating drum while the glass substrate 130 is mounted to a support 162. The rubbing procedure can be performed after forming the orientation layer 134 on the electrode layer 132 on the glass substrate 130. A roll 160 can be covered with a velvet cloth or another suitable cloth or soft material that rotates and under pressure can rub the surface of the orientation layer 134 in a predetermined direction according to an eventual path of light through the cell 101. In some embodiments, the roll 160 can be pressed against the orientation layer 134 by placing a weight (e.g., approximately 5 kg) over the roll 160 or otherwise coupled to the roll 160, and then the velvet is drawn across the substrate at a uniform speed. The pressure used in the load-rubbing is approximately 1 kg/cm². In some embodiments, the load-rubbing can cause some grooving of the surface of the orientation layer. The load-rubbing can achieve some degree of chemical anisotropy to the film to the orientation layer 134 to orient the liquid crystal molecules 112 in the cell 101.

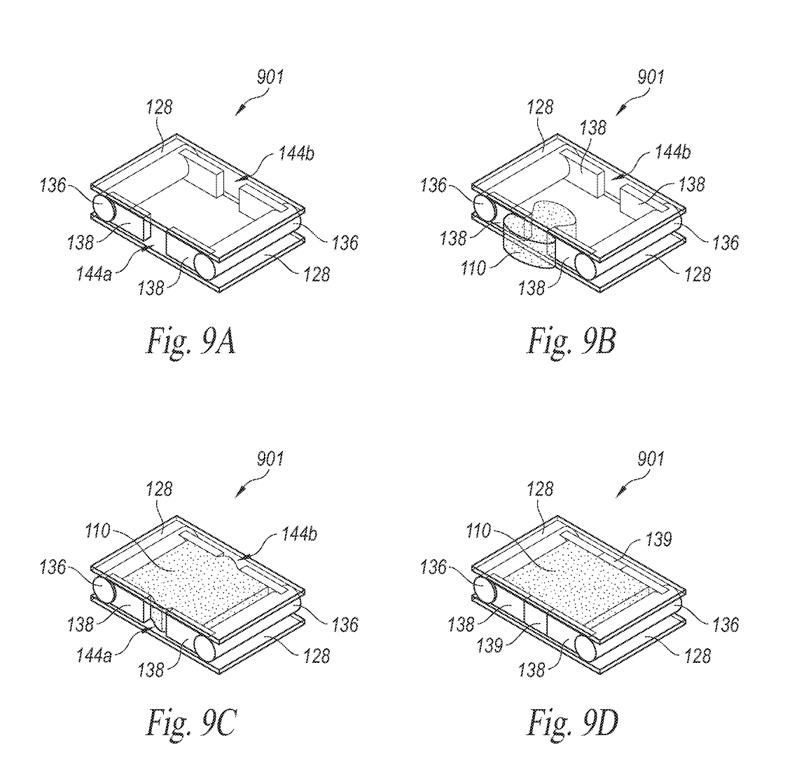

FIGS. 9A-9D are partially schematic, isometric views illustrating a manufacturing process for forming a cell 901 according to embodiments of the present technology. The cell 901 can be generally similar to other cells previously discussed. More specifically, FIGS. 9A-9D illustrate one embodiment of a process for filling the cell 901 with the liquid crystal fluid 110 and sealing the cell 901. Referring first to FIG. 9A, the walls 128 and spacers 136 can be brought together with the spacers 136 between the walls 128. In one embodiment, the spacers 136 can be glass fibers with a diameter of approximately 125 μm. In other embodiments, however, the spacers 136 may have a different size and/or configuration depending on the intended optical path difference and the available voltage source. As mentioned previously, the voltage required to achieve a certain degree of orientation of the liquid crystal molecules 112 is a function of the distance between the walls 128. A UV curable epoxy, such as Norland 65, can be applied to form epoxy doors 138 between the walls 128 and the spacers 136. The doors 138 can partially cover a side of the cell 901, with a first opening 144a on a first side of the cell 901 and a second opening 144b on a second side of the cell 901 opposite the first side of the cell 901.

Referring next to FIG. 9B, a quantity of liquid crystal fluid 110 is placed on the first opening 144a. In some embodiments, capillary action within the cell 901 can be used to pull the liquid crystal fluid 110 through the first opening 144a and into the cell 901. In other embodiments, however, other techniques may be used to apply the liquid crystal fluid 110. FIG. 9C shows the cell 901 with the liquid crystal fluid 110 filling the interior of the cell 901 between the walls 128 and the spacers 136 and the epoxy doors 138.

Referring next to FIG. 9D, a further quantity of epoxy or other suitable material can be placed over the first opening 144a and the second opening 144b to form an epoxy filler 139 to complete the sidewall of the cell 901. The epoxy can be cured with ultraviolet light to maintain the liquid crystal fluid 110 within the cell 901. Epoxy is one type of material that can be used to seal the cell 901. Other curable materials and other types of malleable and formable materials can be used. Virtually any type of seal can be used to close the cell. Once the cell 901 is complete, it can be packaged as a cell for inclusion in a Fourier transform spectroscopy device (not shown) or used in any other suitable application.

As mentioned previously, one feature of the technology disclosed herein is that by passing a beam of light through a cell comprising an electro-sensitive liquid crystal fluid, the optical path difference of the light beam can be measured simply by varying a voltage across the cell. A device including the cells described herein is expected to be more suitable for deployment outside of a carefully controlled laboratory environment than conventional spectrometers because the disclosed technology does not require complex, highly precise moving mirrors or other equipment. Devices including the technology described herein are accordingly expected to be robust, reliable, and effective, and can be provided at a significantly lower cost than many conventional spectrometers.

From the foregoing it will be appreciated that, although specific embodiments of the technology have been described herein for purposes of illustration, various modifications may be made without deviating from the spirit and scope of the technology. For example, a given application can include multiple cells in parallel or in series. Further, certain aspects of the new technology described in the context of particular embodiments may be combined or eliminated in other embodiments. Moreover, while advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein. Thus, the disclosure is not limited except as by the appended claims.

I/We claim:

1. An assembly, comprising:
a cell for altering an optical path distance of a beam of light, the cell comprising—
a pair of transparent walls on opposite sides of the cell;
a liquid crystal fluid within the cell, wherein the liquid crystal fluid has a refractive index that depends, at least in part, upon an orientation of molecules of the liquid crystal fluid, and wherein the orientation of the molecules of the liquid crystal fluid depends, at least in part, upon an electric field within the cell;
a source of electric energy configured to create a variable electric field within the cell;
a light source configured to direct a beam of light through the cell; and
a detector configured to receive the beam of light after the beam of light has passed through the cell and to measure the optical path difference of the beam of light.

2. The assembly of claim 1, further comprising a mirror opposite the light source and configured to reflect the beam of light back through the cell and onto the detector.

3. The assembly of claim 2 wherein the mirror comprises a first mirror, and wherein the assembly further comprises a second mirror opposite the first mirror and configured to reflect the beam of light back through the cell and onto the detector.

4. The assembly of claim 1 wherein the source of electric energy is configured to create the variable electric field across the cell substantially parallel with the beam of light.

5. The assembly of claim 1 wherein the light source includes a lens comprising at least one of a reduction lens and a collimating lens.

6. The assembly of claim 1, further comprising a quartz wave plate positioned in a path of the beam of light.

7. The assembly of claim 1 wherein the light source comprises at least one of a quartz tungsten halogen light source, a laser array, or a light-emitting diode.

8. The assembly of claim 1 wherein the detector comprises at least one of a visible spectrum (silicon-based) detector, NIR (GeAs-based) detector, an infrared (Ge or Cd-based) detector, and a thermopile detector.

9. The assembly of claim 1, further comprising a polarizer between the light source and the cell and an analyzer between the cell and the detector, wherein the polarizer is oriented at approximately 45° relative to the beam of light, and wherein the analyzer is oriented at approximately −45° relative to the beam of light.

10. The assembly of claim 1 wherein each of the transparent walls comprises:
a glass substrate;
an electrode layer on the glass substrate; and
an orientation layer on the electrode layer.

11. The assembly of claim 10 wherein the electrode layer comprises indium tin oxide that is sputter-deposited on the glass substrate.

12. The assembly of claim 10 wherein the orientation layer comprises a polyimide layer of imide monomers.

13. The assembly of claim 1, further comprising spacers between the transparent walls.

14. The assembly of claim 1 wherein the transparent walls are spaced apart by approximately 125 microns.

15. A Fourier transform spectrometer for measuring a refracted beam of light, the spectrometer comprising:
a light source;
a detector configured to receive the beam of light from the light source and measure characteristics of the beam of light;
a cell positioned between the light source and the detector, wherein the cell contains a substance having an index of refraction that is dependent upon an electric field across the cell; and
a power source configured to apply the electric field across the cell in a controllable, variable manner.

16. The Fourier transform spectrometer of claim 15, further comprising an orientation layer in the cell comprising a polymer layer that has been unidirectionally rubbed with a soft tissue.

17. The Fourier transform spectrometer of claim 15, further comprising a first mirror on one side of the cell and a second mirror on another side of the cell, wherein the light source is positioned to direct the beam of light toward the first mirror at a slight angle to reflect the beam of light between the first and second mirrors and eventually toward the detector.

18. The Fourier transform spectrometer of claim 15 wherein the cell contains at least one of a liquid crystal fluid, an electro-optic polymer, cadium tendulum, polymer-based liquid crystal, or polymer-dispersed liquid crystal.

19. A method of manufacturing a cell for a Fourier transform spectrometer, the method comprising:
forming a pair of cell walls by—
depositing an electrode layer on a glass substrate, and
fabricating an orientation layer on the electrode layer;
placing a spacer between the cell walls;
placing a liquid crystal material between the cell walls and the spacer;
forming an epoxy material between the cell walls and around at least a portion of the spacer to seal the liquid crystal material within the cell; and
connecting a power source to the electrode layer on each of the cell walls, wherein the power source is configured to apply a variable electric field across the cell.

20. The method of claim 19, further comprising positioning the cell between two polarizers and in a path of a beam of light with the beam of light passing through the polarizers and the cell.

21. The method of claim 19 wherein the two polarizers comprise a first polarizer at approximately 45° relative to the beam of light, and a second polarizer at approximately 45° relative to the beam of light.

22. The method of claim 19 wherein depositing the electrode layer comprises depositing an optically transparent conductive material on the glass substrate.

23. The method of claim 19 wherein depositing the electrode layer comprises sputtering an indium tin oxide material on the glass substrate.

24. The method of claim 19 wherein fabricating the orientation layer comprises spin coating a polyimide layer on the electrode layer and conditioning the polyimide layer with a velvet cloth.

25. The method of claim 24 wherein conditioning the polyimide layer with the velvet cloth comprises load-rubbing the polyimide layer with a velvet roller.

26. The method of claim 19 wherein placing the liquid crystal material between the cell walls and the spacer comprises:
forming a first opening in the cell and a second opening in the cell, the second opening being opposite the first opening;
depositing a quantity of the liquid crystal material on the first opening to permit capillary action to draw the quantity of liquid crystal material through the opening and into the cell; and
sealing the first opening and the second opening.
